(19) United States
(12) Patent Application Publication
(10) Pub. No.: US 2002/0102498 A1
(43) Pub. Date: Aug. 1, 2002

(54) Method for forming biconvex microlens of image sensor

(76) Inventor: Chih-Hsing Hsin, Chu-Pei City (TW)

Correspondence Address: Powell, Goldstein, Frazer & Murphy, LLP, 1001 Pennsylvanic Avenue, Suite 600, Washington, DC, 20004, US

(21) Appl. No.: 09/774,457

(22) Filed: Jan. 31, 2001

(51) Int. Cl. G03F 7/00

(52) U.S. Cl. 430/321; 430/323; 430/324; 430/330

(57) ABSTRACT

A passivation layer, a color filter layer and a planner layer are formed in order on a substrate. Afterward, a plurality of photoresist layers are defined on the planner layer, wherein a plurality of photoresist layers are formed at a predetermined distance from each other. Subsequently, the planner layer is etched by means of a plurality of photoresist layers as a plurality of etched mask, so as to curve downward the surface of the planner layer. Next, forming a microlens layer on the planner layer and concave surface thereof. The microlens layer is then expose to light by using conventional lithography process to form a plurality of microlens regions. Final, a plurality of biconvex microlens that have lenticular shapes are formed by treating a plurality of microlens regions with a thermal process.

### BACKGROUND OF THE INVENTION

1. Field of the Invention

The present invention relates generally to a method for manufacturing the image sensor devices, and more particularly to a method for forming biconvex microlens.

2. Description of the Prior Art

Image sensor has photodetector devices that detect light, wherein the image sensor can be used for digital camera or scanner. The mechanism of photodetector device is that photons of incident light is translated into electron hole pair, and then induced current proportional to quantity of absorbed photons. Microlenses are in widespread use in conjunction with photodetector arrays, particularly when these utilize photodiodes operating together with charge coupled devices (CCDs). In general, the purpose of the microlens is to focus a pixel's worth of light onto the semiconductor device, thereby increasing the sensitivity of the display. In other words, a microlens is used to focus incident light on a surface of a photodiode.

The solid-state image sensor includes a plurality of photodiodes that are formed in a semiconductor device and convert incident light to an electrical signal by photoelectric conversion to produce a charge. The solid-state image sensor also includes a sense amplifier (SA) that senses the image signal transferred from the charge coupled devices to produce an electrical signal, color filter layers, and microlens over the photodiodes. In a solid-state image sensor, such a microlens is assigned to each photodiode in order that light from an object is focused on the corresponding photodiode of the device through the microlens sequentially to produce an electric signal.

Cross-sectional views of a process for forming microlens of the known prior art are illustrated in FIG. 1A to FIG. 1C. First of all, a substrate 100 is provided. Then a passivation layer 110, a color filter layer 120 and a planner layer 130 as a transparent layer are formed in order thereon. Afterward, a microlens layer 140 is formed on the planner layer 130. Subsequently, a photoresist layer 140 is exposed by means of the lithography process to form a microlens region 150. Finally, performing a thermal process to treat the microlens region 150, so as to fabricate a plano-convex microlens 160 having cambered shape.

Referring to the FIG. 1C, it is obvious that incident light 170 is focused by the plano-convex microlens 160 and then is transmitted through planner layer 130, color filter layer 120 and passivation layer 110 into semiconductor substrate 100. Therefore, it is unassailable that in order to form sensitively photodetector, projective area on the semiconductor substrate 100 of incident light 170 should be as larger as practicable to maximize the absorbed probability of photons. No matter how, owing to the plano-convex microlens 160 of above has a worse focused property, which is difficult to focus incident light on the corresponding photodiode without error, so that causes loss of light and deterioration of resolution. Hence, the sensitivity of conventional image sensor is difficult to be optimized. Furthermore, there is a contact surface, which is a plane, between the planner layer 130 and the plano-convex microlens 160 of above, wherein the plane has a small surface area that results in the adhesive property of microlens material is worse. One of basic concepts for improving the adhesion and focused property of misrolens is introducing a new microlens structure with greater surface area to increase adhesion and focused ability.

In accordance with the above description, a new method for forming microlens is therefore necessary, so as to raise the yield and quality of the follow-up process.

### SUMMARY OF THE INVENTION

In accordance with the present invention, a new method of semiconductor process is provided that substantially overcomes drawbacks of above mentioned problems arised from the conventional methods.

Accordingly, it is an object of the present invention to provide a new method for forming microlens of image sensor. The present invention introduces a microlens, so as to make the projective area of incident light on the reactive region to be efficiently maximized. Thus, the method of the present invention is effective in raising quality of the process.

Another object of the present invention is that provide a method for forming microlens of image sensor. The present invention introduces a biconvex microlens, so as to instead of current plano-convex microlens. The biconvex microlens of this invention can increase focused property to raise the image intensity. Furthermore, this invention can also increase the contact surface area between microlens and planner layer by forming the lenticular shape to raise adhesive property of the microlens.

Still another object of the present invention is that provide a method for forming biconvex microlens of image sensor. In this invention, the surface of the planner layer is curved downward by etched method before coating the microlens layer, so as to form biconvex microlens. Thus, the method of the present invention is easily and to conform to the economic effect, and it is suitable for using in the sub micron.

In accordance with the present invention, a method for forming biconvex microlens of image sensor is disclosed. In embodiment of the present invention, first of all, a substrate is provided. Then a passivation layer, a color filter layer and a planner layer are formed in order thereon. Afterward, a plurality of photoresist layers are defined on the planner layer, wherein a plurality of photoresist layers are formed at a predetermined distance from each other. Subsequently, the planner layer is etched by means of a plurality of photoresist layers as a plurality of etched mask, so as to curve downward the surface of the planner layer. Next, forming a microlens layer on the planner layer and concave surface thereof. The microlens layer is then expose to light by using conventional lithography process to form a plurality of microlens regions. Final, a plurality of biconvex microlens that have lenticular shapes are formed by treating a plurality of microlens regions with a thermal process.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to 1C show cross-sectional views illustrative of various stages of conventional plano-convex microlens process; and

FIG. 2A to 2F show cross-sectional views illustrative of various stages forming the biconvex microlens in accordance with another embodiment of the present invention.

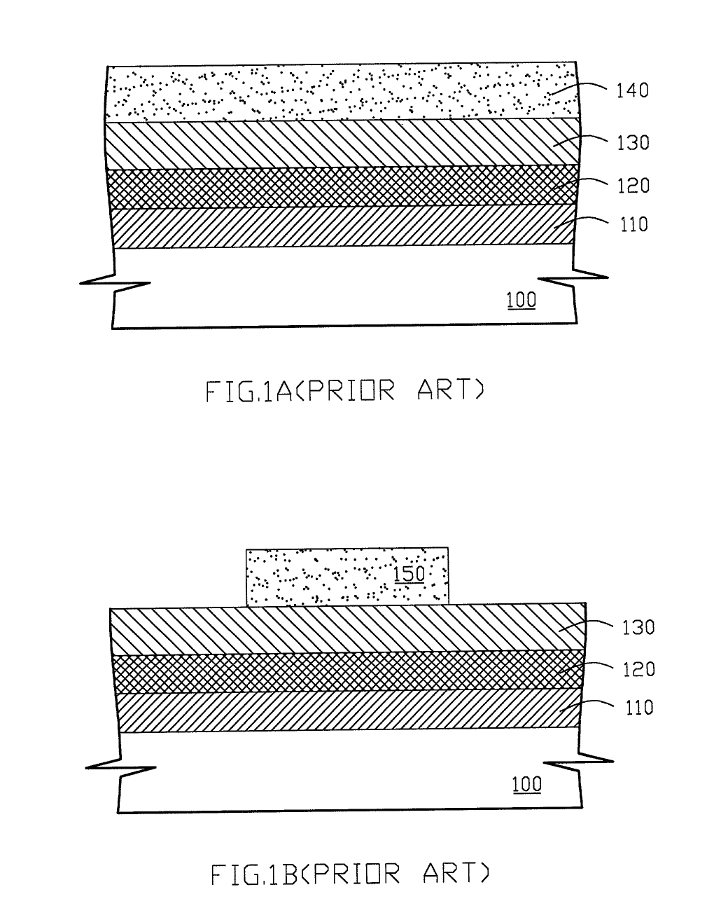

### DESCRIPTION OF THE PREFERRED EMBODIMENT

Preferred embodiments of the present invention will now be described in greater detail. Nevertheless, it should be recognized that the present invention can be practiced in a wide range of other embodiments besides those explicitly described, and the scope of the present invention is expressly not limited except as specified in the accompanying claims.

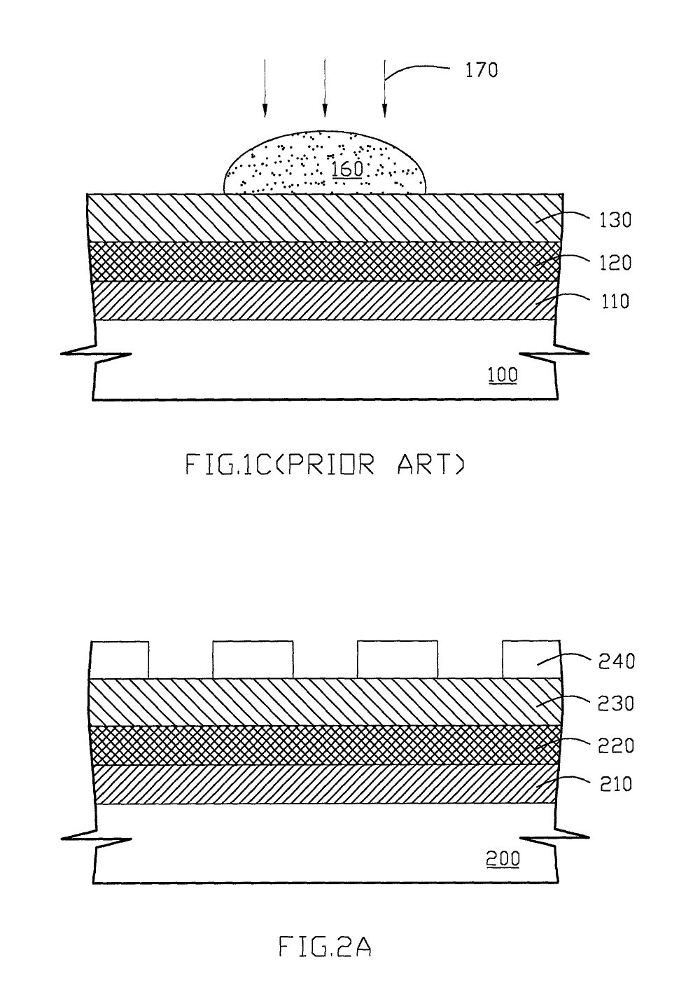

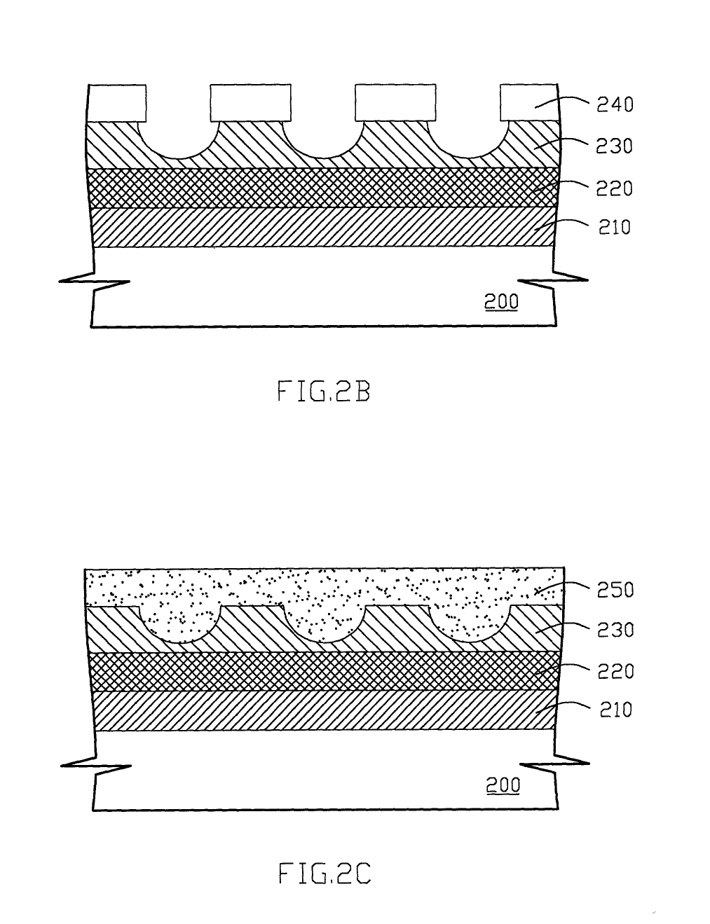

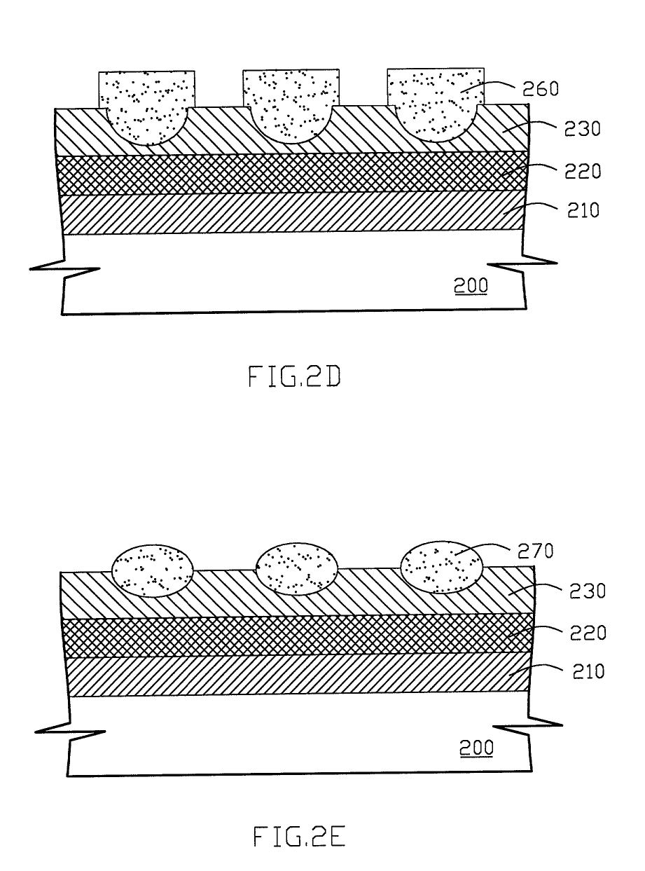

As illustrated in FIG. 2A and FIG. 2B, in embodiment of this invention, first of all, a substrate 200 having a plurality of photodetector devices is provided. Then a passivation layer 210, a color filter layer 220 and a planner layer 230 are formed in order thereon, wherein the planner layer 230 comprises a transparent material, such as Ethylengly colmonoethylether acetate (ECA), Methacryl resin, Multifunctional acrylmonomer. Afterward, a plurality of photoresist layers 240 are defined on the planner layer 230, wherein a plurality of photoresist layers 240 are formed at a predetermined distance from each other and located on a plurality of photodetector devices in the substrate 200. Subsequently, the planner layer 230 is etched by a plurality of photoresist layers 240 as a plurality of etched mask, to form plurality etched regions whose shapes are concave surfaces of planner layer 230, wherein the method for etching the planner layer 230 can use wet or dry etched process to curve downward the surface of the planner layer 230, as shown in FIG. 2C, since the etched processes of above are well known in the prior art, which are not the focus of the present invention, hence will not be described in greater details.

Referring to FIG. 2D and FIG. 2E, in this embodiment, a photosensitive layer 250 is coated on the planner layer 230 and concave surfaces thereof by a spin-on process with a photosensitive material after a plurality of photoresist layers 240 are removed, wherein the thickness of the photosensitive layer 250 is less then about 5 micrometer. The photosensitive layer 250 is then expose to light by using conventional lithography process to form plurality photosensitive regions 260 that are located on the concave surfaces of the planner layer 230. Final, plurality photosensitive regions 260 are treated with a thermal process while forming a plurality of biconvex microlens 270 that have lenticular shape, as shown in FIG. 2F.

In the embodiments of the present invention, a new method for forming microlens of image sensor is provided. The present invention introduces a microlens, so as to make the projective area of incident light on the reactive region to be efficiently maximized. Thus, the method of the present invention is effective in raising quality of the process. Furthermore, the present invention can instead of current plano-convex microlens by forming a biconvex microlens, so as to increase focused property to raise the image intensity. Moreover, this invention can also increase the contact surface area between microlens and planner layer by forming the lenticular shape to raise adhesive property of the microlens. On the other hand, in this invention, the surface of the planner layer is curved downward by etched method before coating the microlens layer, so as to form biconvex microlens. Thus, the method of the present invention is easily and to conform to the economic effect, and it is suitable for using in the sub micron. Method of the present invention is the best microlens compatible process for deep sub-micro process.

Obviously, many modifications and variations of the present invention are possible in light of the above teachings. It is therefore to be understand that within the scope of the appended claims, the present invention may be practiced otherwise than as specifically described herein.

Although specific embodiments have been illustrated and described, it will be obvious to those skilled in the art that various modifications may be made without departing from what is intended to be limited solely by the appended claims.

What is claimed is:

1. A method for forming a microlens, comprising:
providing a substrate;
forming a planner layer on said substrate;
defining a photoresist layer on said planner layer;
etching said planner layer by said photoresist layer as a etched mask to form a etched region on said planner layer;
removing said photoresist layer;
forming a microlens layer on said etched region of said planner layer; and
forming said microlens on said etched region of said planner layer.

2. The method according to claim 1, wherein said substrate comprises a photodetector device.

3. The method according to claim 1, wherein said planner layer comprises a transparent material.

4. The method according to claim 1, wherein the method for etching said planner layer comprises a wet etched process.

5. The method according to claim 1, wherein the method for etching said planner layer comprises a dry etched process.

6. The method according to claim 1, wherein said etched region comprises a concave surface of said planner layer.

7. The method according to claim 1, wherein said microlens layer comprises a photosensitive material.

8. The method according to claim 1, wherein the method for forming said microlens layer comprises a spin-on process.

9. The method according to claim 1, wherein the method for forming said microlens comprises a thermal process.

10. A method for forming a microlens of a image sensor, comprising:
providing a substrate having a photodetector device;
forming a planner layer on said substrate;
defining a photoresist layer on said planner layer;
etching said planner layer by said photoresist layer as a etched mask to form a concave surface on said planner layer as a etched region;
removing said photoresist layer;
forming a photosensitive layer on said etched region of said planner layer by a spin-on process; and
treating said photosensitive layer on said etched region of said planner layer with a thermal process to form said microlens.

11. The method according to claim 10, wherein said planner layer comprises a transparent material.

12. The method according to claim 10, wherein the method for etching said planner layer comprises a wet etched process.

13. The method according to claim 10, wherein the method for etching said planner layer comprises a dry etched process.

14. The method according to claim 10, wherein said etched region is located on said photodetector of said substrate.

15. The method according to claim 10, wherein the thickness of said photosensitive layer is less than about 5 micrometer.

16. A method for forming a microlens, comprising:
providing a substrate;
forming a passivation layer on said substrate;
forming a color filter layer on passivation layer;
forming a planner layer on said color filter layer;
defining a photoresist layer on said planner layer;
etching said planner layer by said photoresist layer as a etched mask to form a etched region on said planner layer;
removing said photoresist layer;
forming a microlens layer on said planner layer;
forming a microlens region on said etched region of said planner layer; and
treating said microlens region on said etched region of said planner layer to form said microlens.

17. The method according to claim 16, wherein said substrate comprises a photodetector device.

18. The method according to claim 16, wherein said planner layer comprises a transparent material.

19. The method according to claim 16, wherein the method for etching said planner layer comprises a wet etched process.

20. The method according to claim 16, wherein the method for etching said planner layer comprises a dry etched process.

21. The method according to claim 16, wherein said etched region comprises a concave surface of said planner layer.

22. The method according to claim 16, wherein said microlens layer comprises a photosensitive material.

23. The method according to claim 16, wherein the method for forming said microlens layer comprises a spin-on process.

24. The method according to claim 16, wherein the method for forming said microlens comprises a thermal process.

25. The method according to claim 16, wherein the method for forming said microlens comprises a thermal process.

26. A method for forming a microlens of a image sensor, comprising:
providing a substrate having a photodetector device;
forming a passivation layer on said substrate;
forming a color filter layer on passivation layer;
forming a planner layer on said color filter layer;
defining a photoresist layer on said planner layer;
etching said planner layer by said photoresist layer as a etched mask to form a concave surface on said planner layer as a etched region;
removing said photoresist layer;
forming a photosensitive layer on said planner layer by a spin-on process;
forming a photosensitive region on said etched region of said planner layer; and
treating said photosensitive region on said etched region of said planner layer with a thermal process to form said microlens.

27. The method according to claim 26, wherein said planner layer comprises a transparent material.

28. The method according to claim 26, wherein the method for etching said planner layer comprises a wet etched process.

29. The method according to claim 26, wherein the method for etching said planner layer comprises a dry etched process.

30. The method according to claim 26, wherein said etched region is located on said photodetector of said substrate.

31. The method according to claim 26, wherein the thickness of said photosensitive layer is less than about 5 micrometer.

32. The method according to claim 26, wherein the method for forming said photosensitive region comprises a photography process.

33. A method for forming a plurality of biconvex microlens of a image sensor, comprising:
providing a substrate having a plurality of photodetector device;
forming a passivation layer on said substrate;
forming a color filter layer on passivation layer;
forming a planner layer on said color filter layer;
defining a plurality of photoresist layers on said planner layer;
etching said planner layer by said plurality of photoresist layers as a plurality of etched masks to form a plurality of etched regions with a plurality of concave surfaces on said planner layer, wherein said plurality of etched regions are located on said plurality of photodetector device in said substrate;
removing said plurality of photoresist layer;
coating a photosensitive layer, which has a thickness is less then about 5 micrometer, on said planner layer by a spin-on process with a photosensitive material;
forming a plurality of photosensitive regions on said plurality of etched regions of said planner layer; and
treating said plurality of photosensitive regions with a thermal process to form said plurality of microlens on said planner layer.

34. The method according to claim 33, wherein said planner layer comprises a transparent material.

35. The method according to claim 33, wherein the method for etching said planner layer comprises a wet etched process.

36. The method according to claim 33, wherein the method for etching said planner layer comprises a dry etched process.
